(19) United States
(12) Patent Application Publication
(10) Pub. No.: US 2022/0340411 A1
(43) Pub. Date: Oct. 27, 2022

(54) MEMS ROTOR WITH COATED BOTTOM SURFACE

(71) Applicant: MURATA MANUFACTURING CO., LTD., Nagaokakyo-shi (JP)

(72) Inventor: Petteri KILPINEN, Espoo (FI)

(21) Appl. No.: 17/725,411

(22) Filed: Apr. 20, 2022

(30) Foreign Application Priority Data
Apr. 22, 2021 (FI) 20215470

(51) Int. Cl. B81B 5/00; B81C 1/00

(52) U.S. Cl. CPC B81B 5/00; B81C 1/00198; B81B 2201/0235; B81B 2201/0242; B81B 2203/0315; B81B 2203/06; B81C 2203/036

(57) ABSTRACT

This disclosure describes a comprising a handle wafer and a device wafer which is bonded to the handle wafer. The handle wafer comprises a cavity and the device wafer comprises a mobile rotor part above the cavity. A bottom coating layer covers at least a part of the bottom surface of the rotor.

### FIELD OF THE DISCLOSURE

This disclosure relates to micromechanical devices, and particularly to micromechanical devices formed in a device wafer which is bonded to a handle wafer. The present disclosure further concerns the mass of a mobile rotor formed in the device wafer.

### BACKGROUND OF THE DISCLOSURE

Microelectromechanical (MEMS) devices are typically manufactured from silicon substrates. The micromechanical structures may be formed in a device wafer which has been bonded to a thicker handle wafer for structural support. The micromechanical structures often include a rotor which is mobile in relation to the fixed parts of the device wafer. A cavity can be formed in the region of the handle wafer which will lie beneath the rotor.

The formation of microelectromechanical structures in the device wafer usually requires gaps which are etched all the way through the device wafer. The deep-etch processes by which such gaps are produced will often leave structural irregularities in these gaps if the device wafer is thick. The likelihood of irregularities will be lower—and the yield of the manufacturing process will consequently be better—if the device wafer is thinner.

However, very thin device wafers can lead to other challenges in devices such as accelerometers and gyroscopes, where an output signal is produced by measuring the movement of a rotor which has been etched in the device wafer. The output signal becomes more sensitive to small fluctuations in the surrounding environment if the device wafer is very thin and the rotor has a very small mass.

A rotor with greater surface area will be heavier, but it is typically not a good solution to increase the weight of the rotor by increasing its surface area. The increased area required will also lead to a lower yield when less MEMS chips fit on one device wafer. It would be preferable to use a thin device wafer with a sufficiently heavy rotor without having to increase the surface area of the MEMS chip.

### BRIEF DESCRIPTION OF THE DISCLOSURE

An object of the present disclosure is to provide an apparatus and method which overcome the above problems.

The object of the disclosure is achieved by a method and an arrangement which are characterized by what is stated in the independent claims. The preferred embodiments of the disclosure are disclosed in the dependent claims.

The disclosure is based on the idea of depositing an additional layer on the surface of a rotor in a device wafer before the device wafer is bonded to a handle wafer. This increases the mass of the rotor. An advantage of this arrangement is that a very thin device wafer can be used.

### BRIEF DESCRIPTION OF THE DRAWINGS

In the following the disclosure will be described in greater detail by means of preferred embodiments with reference to the accompanying drawings, in which

FIGS. 1a-1c illustrate a MEMS component where the bottom surface of the rotor is coated, and a method for manufacturing such a component.

FIG. 1d illustrates a bottom coating layer which covers a symmetric middle area on the rotor bottom surface.

FIG. 2 illustrates illustrate a MEMS component where both the top and the bottom surfaces of the rotor are coated.

FIGS. 3a-3b illustrate a suspension arrangement.

### DETAILED DESCRIPTION OF THE DISCLOSURE

This disclosure relates to method for manufacturing a MEMS component. The method comprises the steps of (1) forming a cavity on a top surface of a silicon handle wafer, (2) bonding a bottom surface of a silicon device wafer onto the top surface of the handle wafer so that the device wafer covers the cavity, and (3) forming microelectromechanical structures comprising a fixed stator part and a mobile rotor part in the device wafer. The mobile rotor part has a rotor bottom surface and a rotor top surface. The mobile rotor part is suspended from the fixed stator part above the cavity. The method also comprises the step of depositing a bottom coating layer on at least a part of the rotor bottom surface before the device wafer is bonded to the handle wafer.

In this disclosure, the surfaces of the device wafer and the handle wafer define an xy-plane which may be referred to as the device plane. The direction which is perpendicular to the device plane is illustrated with the z-axis and referred to as the vertical direction. Words such as “top” and “bottom” refer to vertically separated sides. These words do not imply anything about how the MEMS device should be oriented during usage or during manufacturing. The word “thickness” refers in this disclosure to the z-dimension.

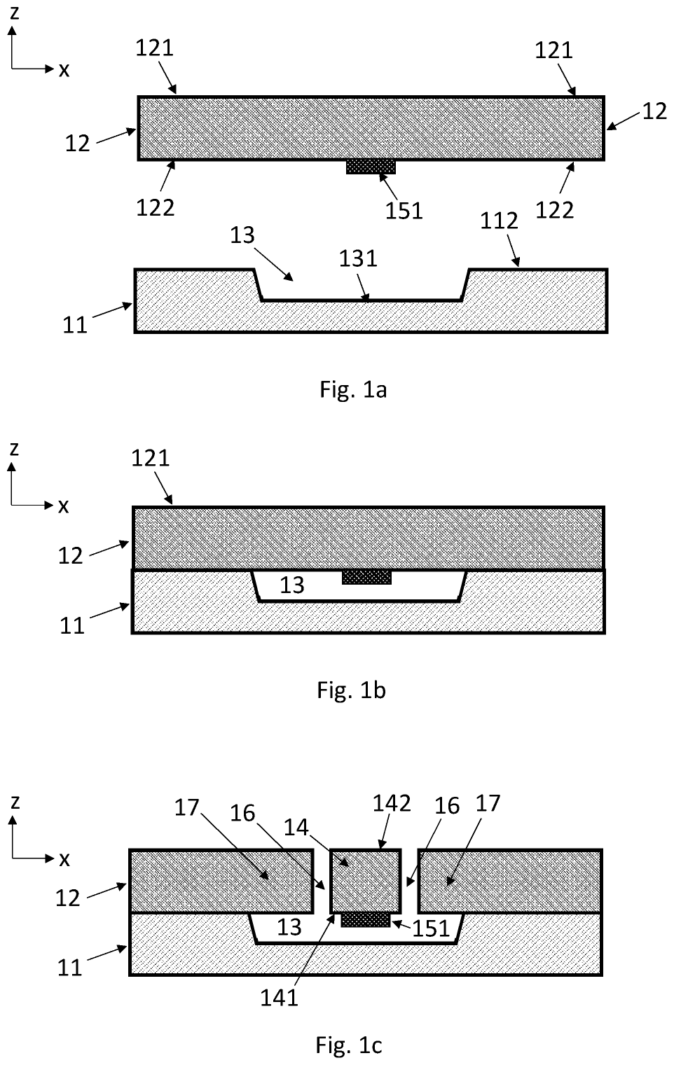

FIGS. 1a-1c illustrate the method. The figure illustrates a handle wafer 11 and a device wafer 12. These two wafers may be prepared separately before they are bonded together. The handle wafer 11 has a top surface 112. A cavity 13 is prepared on the top side of the handle wafer by etching. The cavity 13 then has a cavity floor 131 which forms the bottom of the cavity.

The device wafer 12 has a top surface and a bottom surface 122. A bottom coating layer 151 is deposited on the bottom surface 122 of the device wafer 12. This bottom coating layer 151 is positioned so that it is located in a region of the bottom surface 122 which will, in a later stage of the manufacturing process, form the bottom surface of the rotor.

In the next method step, illustrated in FIG. 1b, the bottom surface of the device wafer 12 is bonded to the top surface of the handle wafer 11, for example by fusion bonding. The part of the device wafer 12 which comprises the bottom coating layer 151 is aligned with the cavity 13 in the handle wafer 11. Alignment marks may be implemented on the handle wafer and the device wafer to achieve good alignment.

FIG. 1c illustrates the third step of the manufacturing method. Gaps such as 16 are etched in the device wafer 12 to separate the rotor part 14, which will be mobile, from adjacent stator parts in the device wafer, such as 17, whose positions are fixed in relation to the handle wafer. In practice, the rotor part 14 may be suspended from the stator parts 17 with flexible suspenders which allow the rotor part to undergo movement when it is affected by a force. Suspenders are not illustrated in FIG. 1c.

The rotor part 14 has a rotor bottom surface 141 and a rotor top surface 142. As explained above and illustrated in FIG. 1c, the bottom coating layer 151 was deposited in the region of the device wafer 12 which now forms at least a part of the rotor bottom surface 141.

The bottom coating layer 151 may cover substantially the entire rotor bottom surface 141. Alternatively, as illustrated in FIG. 1d, the bottom coating layer 151 may cover a middle area on the rotor bottom surface 141, so that the layer 151 is not present on the edges of the rotor bottom surface 141. The middle area may be symmetric with respect to the center of gravity of the rotor in the xy-plane.

The material of the bottom coating layer 151 may for example be gold, copper, silver, tungsten, tantalum, yttrium, neodymium, cerium, lanthanum, zirconium, indium, niobium, molybdenum or hafnium. This material may alternatively be a carbide of tungsten, tantalum, yttrium, neodymium, cerium, lanthanum, zirconium, indium, niobium, molybdenum or hafnium, for example WC, TaCₓ, where x is between 0.4 and 1, YC₂, NdC₂, CeC₂, CeC₂, ZrC, NbC, Nb₂C, MoC, Mo₂C, or HfC. As a further alternative, the material of the bottom coating layer may be a nitride of tungsten, tantalum, yttrium, neodymium, cerium, lanthanum, zirconium, indium, niobium, molybdenum or hafnium, for example WN, WN₂, TaN or HfN. Finally, the material of the bottom coating layer may be an oxide of tungsten, tantalum or yttrium, for example WO₃, T12O₅ or Y₂O₃. It could alternatively be a nitride-carbide, oxide-carbide or nitride-oxide composite of any element listed above, or a compound material which comprises two or more of the materials listed above. These material options apply to all coating layers (top and bottom) described in this disclosure.

The density of the material of the bottom coating layer 151 may be greater than the density of silicon. The density of the material of the bottom coating layer 151 may for example be in the range 5-50 g/cm³, 10-50 g/cm³ or 15-30 g/cm³. The density of the material in coating layer 151 may alternatively be greater than 5 g/cm³, greater than 10 g/cm³, greater than 15 g/cm³, greater than 20 g/cm³ or greater than 30 g/cm³. The thickness of the bottom coating layer 151 in the vertical direction may for example be in the range 50 nm-50 μm, 500 nm-50 μm, 1-50 μm, 1-10 μm, 1-20 μm, 10-50 μm, 10-30 μm or 20-50 μm. The thickness of the coating layer 151 may alternatively be greater than 50 nm, greater than 500 nm, greater than 1 μm, greater than 10 μm, greater than 25 μm or greater than 50 μm. These density and thickness options apply to all coating layers (top and bottom) described in this disclosure. Any thickness option listed above can be combined with any density option listed above. Any thickness option listed above can also be combined with any material option listed above.

This disclosure also describes a MEMS component comprising a silicon handle wafer 11 with a top surface 112 which defines a horizontal plane. The top surface 112 also defines a vertical direction which is perpendicular to the horizontal plane. The MEMS component further comprises a silicon device wafer 12 with a bottom surface 122 and a top surface 121.

The handle wafer 11 comprises a cavity 13 which is delimited by a cavity floor 131 which is recessed in the vertical direction from the top surface 112 of the handle wafer 11. The device wafer 12 comprises a fixed stator part 17 and a mobile rotor part 14. The mobile rotor part 14 has a rotor bottom surface 141 and a rotor top surface 142. The mobile rotor 14 part is above the cavity floor 131. The MEMS component comprises a bottom coating layer 151 which covers at least a part of the rotor bottom surface 141.

The MEMS component may for example be an accelerometer or a gyroscope.

The method described above may also comprise the further step of depositing a top coating layer on at least a part of the rotor top surface. Correspondingly, the MEMS component may comprise a top coating layer which covers at least a part of the rotor top surface.

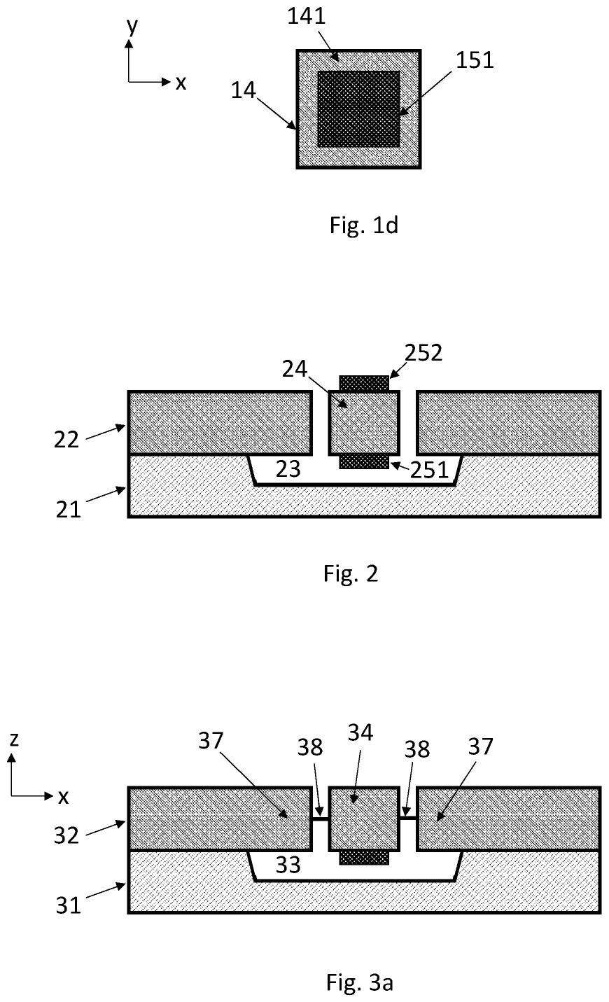

FIG. 2 illustrates a component where reference number 21-24 and 251 correspond to reference numbers 11-14 and 151, respectively, in FIGS. 1a-1d. A top coating layer 252 has been deposited on the top surface of the rotor 24. The top coating layer 252 may be deposited on the device wafer 22 before the device wafer 22 is bonded to the handle wafer 21, or it may be deposited on the device wafer 22 after the device wafer 22 has been bonded to the handle wafer 21. The density of the top coating layer may be greater than the density of the of silicon.

It will in some cases be beneficial to make the top coating layer symmetric with the bottom coating layer. The center of gravity of the rotor part after the top and bottom coating layers have been deposited may be in the same position where the center of gravity of the rotor part had been if no bottom coating layer and no top coating layer had been deposited on the rotor part.

The material of the bottom coating layer may be the same as the material of the top coating layer. Furthermore, the vertical thickness of the top coating layer may be substantially equal to the vertical thickness of the bottom coating layer. And finally, the area covered by the bottom coating layer on the rotor bottom surface may be substantially aligned in the vertical direction with the area covered by the top coating layer on the rotor top surface.

Any material option listed above for the bottom coating layer can be applied also in the top coating layer. The material of the top coating layer may be different from the material of the bottom coating layer. Furthermore, any density option listed above for the material of the bottom coating layer may apply also to the material of the top coating layer. The density of the top coating layer may be different from the density of the bottom coating layer. Finally, any thickness option listed above for the bottom coating layer may apply also to the top coating layer. The thickness of the top coating layer may be different from the thickness of the bottom coating layer.

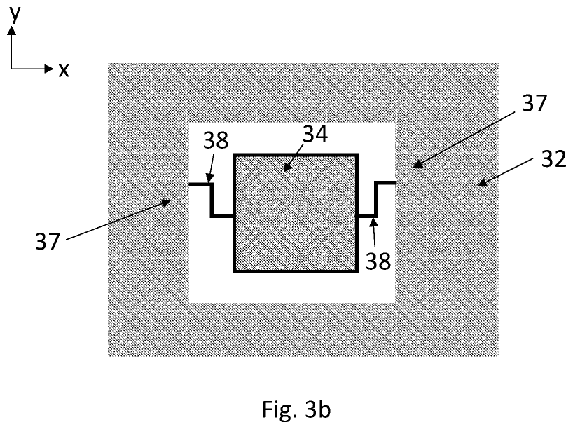

FIGS. 3a-3b illustrate a component where reference numbers 31-34 and 37 correspond to reference numbers 11-14 and 37, respectively, in FIGS. 1a-1d. The embodiment shown in FIGS. 3a-3b can also be implemented with the top coating layer which FIG. 2 illustrates.

FIGS. 3a and 3b illustrate a suspension arrangement. The rotor part 34 is suspended from stator parts 37 by flexible suspenders 38 which extend from the rotor part to the stator part. The suspenders 38 allow the rotor part 34 to move in relation to the stator parts 37, which in this case means motion in relation to the device wafer 32. The flexible suspenders may extend from the rotor part to the stator part on at least two sides of the rotor part. These at least two sides may comprise two opposite sides of the rotor, as FIGS. 3a and 3b illustrate. Alternatively, the at least two sides may comprise two sides which are not opposite to each other, or they may comprise three or four sides of the rotor.

The flexible suspenders 38 may be flexible in the vertical direction (z), so that they allow the rotor part 34 to move in a vertical direction with respect to the stator parts 37. Alternatively, the flexible suspenders 38 may be flexible in one or more horizontal directions (x and/or y), so that they allow the rotor part 34 to move in a horizontal direction. Another alternative is that the flexible suspenders are flexible in all three directions (x,y,z) and allow movement in all of these directions.

1. A MEMS component, comprising:
a silicon handle wafer with a top surface which defines a horizontal plane, whereby the top surface also defines a vertical direction which is perpendicular to the horizontal plane; and
a silicon device wafer with a bottom surface and a top surface,
wherein the silicon handle wafer comprises a cavity which is delimited by a cavity floor which is recessed in the vertical direction from the top surface of the handle wafer,
and wherein the silicon device wafer comprises a fixed stator part and a mobile rotor part, wherein the mobile rotor part has a rotor bottom surface and a rotor top surface, and the mobile rotor part is above the cavity floor;
the MEMS component further comprising a bottom coating layer which covers at least a part of the rotor bottom surface.

2. The MEMS component according to claim 1, wherein a density of a material of the bottom coating layer is greater than a density of silicon.

3. The MEMS component according to claim 1, further comprising a top coating layer which covers at least a part of the rotor top surface.

4. The MEMS component according to claim 3, wherein a density of a material of the top coating layer is greater than a density of silicon.

5. The MEMS component according to claim 3, wherein a material of the bottom coating layer is same as a material of the top coating layer.

6. The MEMS component according to claim 5, wherein a vertical thickness of the top coating layer is substantially equal to a vertical thickness of the bottom coating layer, and an area covered by the bottom coating layer on the rotor bottom surface is substantially aligned in a vertical direction with an area covered by the top coating layer on the rotor top surface.

7. A method for manufacturing a MEMS component, comprising:
- forming a cavity on a top surface of a silicon handle wafer;
- bonding a bottom surface of a silicon device wafer onto the top surface of the silicon handle wafer so that the silicon device wafer covers the cavity;
- forming microelectromechanical structures comprising a fixed stator part and a mobile rotor part in the silicon device wafer, wherein the mobile rotor part has a rotor bottom surface and a rotor top surface, and the mobile rotor part is suspended from the fixed stator part above the cavity; and
- depositing a bottom coating layer on at least a part of the rotor bottom surface before the silicon device wafer is bonded to the silicon handle wafer.

8. The method according to claim 7, whereina density of a material of the bottom coating layer is greater than a density of silicon.

9. The method according to claim 6, further comprising depositing a top coating layer on at least a part of the rotor top surface.

10. The method according to claim 8, whereina density of a material of the top coating layer is greater than the density of silicon.

11. The method according to claim 8, wherein the material of the bottom coating layer is same as a material of the top coating layer.

12. The method according to claim 11, wherein a thickness of the top coating layer is substantially equal to a thickness of the bottom coating layer, and an area covered by the bottom coating layer on the rotor bottom surface is substantially aligned in a vertical direction with an area covered by the top coating layer on the rotor top surface.
